(19) United States
(12) Patent Application Publication
(10) Pub. No.: US 2019/0355894 A1
(43) Pub. Date: Nov. 21, 2019

(54) ACOUSTICALLY PRODUCING A BIAS VOLTAGE

(71) Applicant: uBeam Inc., Santa Monica, CA (US)

(72) Inventor: Hong Gao, Marina del Rey, CA (US)

(21) Appl. No.: 15/981,300

(22) Filed: May 16, 2018

(51) Int. Cl. H01L 41/113; H01L 41/047; H01L 41/04; H05K 1/18; H05K 3/30

(52) U.S. Cl. CPC H01L 41/113; H01L 41/047; H01L 41/042; H05K 2201/10174; H05K 3/303; H05K 2201/10083; H05K 2201/10015; H05K 1/181

(57) ABSTRACT

Electrical power for an electrical device can be acoustically produced. A first portion of an acoustic energy can be received at a piezoelectric transducer. A first electrical energy, produced from the first portion of the acoustic energy, can be conveyed from the piezoelectric transducer and received by a circuit. A bias voltage, produced from the first electrical energy, can be conveyed from the circuit and received at a capacitive transducer. A second portion of the acoustic energy can be received at the capacitive transducer. A second electrical energy, produced from the second portion of the acoustic energy, can be conveyed from the capacitive transducer and used as the electrical power for the electrical device. A ratio of the second electrical energy to the second portion of the acoustic energy can be greater than a ratio of the first electrical energy to the first portion of the acoustic energy.

### TECHNICAL FIELDS

The disclosed technologies are related to at least the technical fields of energy harvesting, ultrasonic transducers, piezoelectric transducers, and capacitive transducers.

### BACKGROUND

An ultrasonic transducer can convert between acoustic energy and electrical energy. Typically, the acoustic energy can include sound waves at frequencies higher than an audible limit of human hearing: ultrasound. Generally, an ultrasonic transducer can be one of two types: a piezoelectric transducer and a capacitive transducer. A piezoelectric transducer can include a piezoelectric material between a pair of electrodes. The piezoelectric material can move (e.g., change a size, a shape, or both) in response to a voltage being applied between the pair of electrodes. Conversely, the piezoelectric material can produce a voltage between the pair of electrodes in response to a force that causes the piezoelectric material to move (e.g., change a size, a shape, or both). A capacitive transducer can include a cavity between a pair of electrodes. The pair of electrodes can include a conductive diaphragm and a backing plate. A bias voltage can be applied between the pair of electrodes. With the bias voltage applied between the pair of electrodes, the conductive diaphragm can move in response to an alternating voltage being applied between the pair of electrodes. Conversely, with the bias voltage applied between the pair of electrodes, an alternating voltage can be produced in response to a force that causes the conductive diaphragm to move.

### BRIEF SUMMARY

According to an implementation of the disclosed technologies, a system for producing a bias voltage can include a piezoelectric transducer and a circuit. The piezoelectric transducer can be configured to receive an acoustic energy. The piezoelectric transducer can have a pair of electrodes. The pair of electrodes can be configured to convey an electrical energy. The circuit can have an input and an output. The input can be configured to receive the electrical energy. The output can be configured to convey the bias voltage.

According to an implementation of the disclosed technologies, in a method for producing a bias voltage, an acoustic energy can be received at a piezoelectric transducer. An electrical energy, produced from the acoustic energy, can be conveyed from the piezoelectric transducer. The electrical energy can be received at a circuit. The bias voltage, produced from the electrical energy, can be conveyed from the circuit.

According to an implementation of the disclosed technologies, in a method for making a system for producing a bias voltage, a piezoelectric transducer can be mounted on a printed circuit board. The piezoelectric transducer can be configured to receive an acoustic energy. The piezoelectric transducer can have a pair of electrodes. The pair of electrodes can be configured to convey an electrical energy. An integrated circuit chip can be mounted on the printed circuit board. The integrated circuit chip can have an input and an output. The input can be configured to receive the electrical energy. The output can be configured to convey the bias voltage.

Additional features, advantages, and aspects of the disclosed technologies are set forth or apparent from consideration of the following detailed description, drawings, and claims. Moreover, it is to be understood that both the foregoing summary and the following detailed description are illustrative and are intended to provide further explanation without limiting the scope of the claims.

### BRIEF DESCRIPTION OF THE DRAWINGS

The accompanying drawings, which are included to provide a further understanding of the disclosed technologies, are incorporated in and constitute a part of this specification. The drawings also illustrate aspects of the disclosed technologies and together with the detailed description serve to explain the principles of aspects of the disclosed technologies. No attempt is made to show structural details in more detail than may be necessary for a fundamental understanding of the disclosed technologies and various ways in which they may be practiced.

FIG. 1 is a block diagram illustrating an example environment for an example of a system for producing a bias voltage according to the disclosed technologies.

FIG. 2 is a schematic diagram illustrating an example of the circuit according to the disclosed technologies.

FIG. 3 is a schematic diagram illustrating another example of the circuit according to the disclosed technologies.

FIG. 4 is a block diagram illustrating yet another example of the circuit according to the disclosed technologies.

FIG. 5 is a block diagram illustrating still another example of the circuit according to the disclosed technologies.

FIG. 6 is a flow diagram illustrating an example of a method for producing a bias voltage according to the disclosed technologies.

FIG. 7 is a flow diagram illustrating an example of a method for making a system for producing a bias voltage according to the disclosed technologies.

### DETAILED DESCRIPTION

As used herein, a statement that a component can be “configured to” perform an operation can be understood to mean that the component requires no structural alterations, but merely needs to be placed into an operational state (e.g., be provided with electrical power, have an underlying operating system running, etc.) in order to perform the operation.

An ultrasonic transducer can convert between acoustic energy and electrical energy. Typically, the acoustic energy can include sound waves at frequencies higher than an audible limit of human hearing: ultrasound. Generally, an ultrasonic transducer can be one of two types: a piezoelectric transducer and a capacitive transducer. A piezoelectric transducer can include a piezoelectric material between a pair of electrodes. The piezoelectric material can move (e.g., change a size, a shape, or both) in response to a voltage being applied between the pair of electrodes. Conversely, the piezoelectric material can produce a voltage between the pair of electrodes in response to a force that causes the piezoelectric material to move (e.g., change a size, a shape, or both). A capacitive transducer can include a cavity between a pair of electrodes. The pair of electrodes can include a conductive diaphragm and a backing plate. A bias voltage can be applied between the pair of electrodes. With the bias voltage applied between the pair of electrodes, the conductive diaphragm can move in response to an alternating voltage being applied between the pair of electrodes. Conversely, with the bias voltage applied between the pair of electrodes, an alternating voltage can be produced in response to a force that causes the conductive diaphragm to move.

Electrical power for an electrical device can be acoustically produced by an ultrasonic transducer. Theoretically, a capacitive transducer can be more efficient than a piezoelectric transducer at converting from acoustic energy to electrical energy. However, as described above, operation of a capacitive transducer requires that a bias voltage be applied between the pair of electrodes of the capacitive transducer. The disclosed technologies provide, for example, a system for producing a bias voltage that can include a piezoelectric transducer and a circuit. The piezoelectric transducer can be configured to receive a first portion of an acoustic energy. The piezoelectric transducer can have a first pair of electrodes configured to convey a first electrical energy. The circuit can have an input and an output. The input can be configured to receive the first electrical energy. The output can be configured to convey the bias voltage. Optionally, the system can further include a capacitive transducer. The capacitive transducer can be configured to receive a second portion of the acoustic energy. The capacitive transducer can have a second pair of electrodes configured to receive the bias voltage and to convey a second electrical energy. Optionally, the system can be a component of the electrical device. The electrical device can be configured to use the second electrical energy as the electrical power for the electrical device. A ratio of the second electrical energy to the second portion of the acoustic energy can be greater than a ratio of the first electrical energy to the first portion of the acoustic energy. In this manner, the electrical power for the electrical device can be acoustically produced efficiently by the capacitive transducer by having the required bias voltage produced by the piezoelectric transducer.

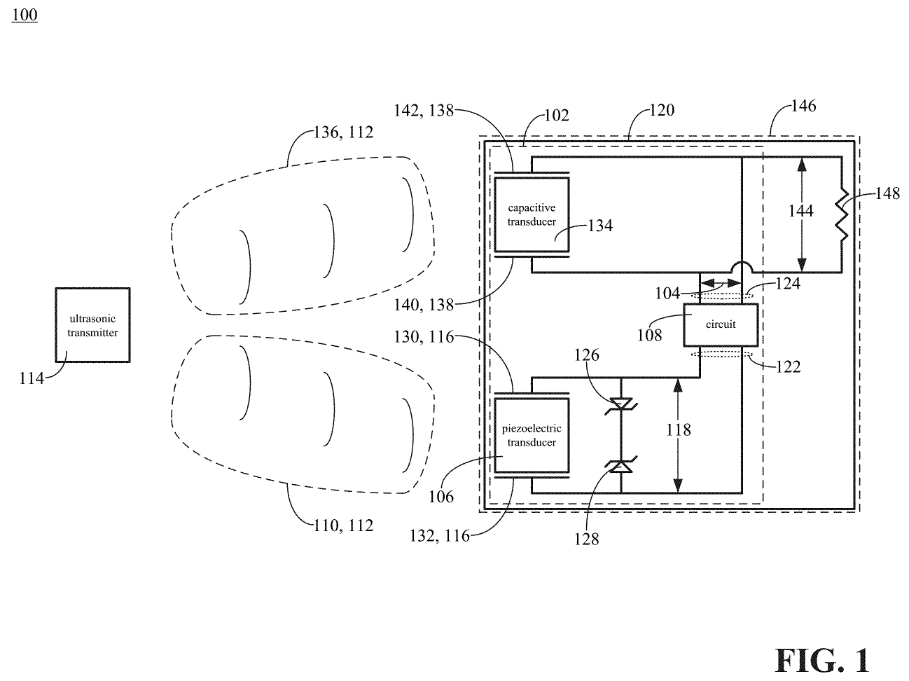

FIG. 1 is a block diagram illustrating an example environment 100 for an example of a system 102 for producing a bias voltage 104 according to the disclosed technologies. The system 102 can include a piezoelectric transducer 106 and a circuit 108.

The piezoelectric transducer 106 can be configured to receive a first portion 110 of an acoustic energy 112. For example, the acoustic energy 112 can include a sound wave at an ultrasound frequency. For example, the acoustic energy 112 can be transmitted by an ultrasonic transmitter 114. The piezoelectric transducer 106 can have a first pair of electrodes 116. The first pair of electrodes 116 can be configured to convey a first electrical energy 118. For example, the piezoelectric transducer 106 can be a microelectromechanical device. For example, the piezoelectric transducer 106 can be a surface mount device. Optionally, the piezoelectric transducer 106 can be mounted on a printed circuit board 120.

The circuit 108 can have an input 122 and an output 124. The input 122 can be configured to receive the first electrical energy 118. The output 124 can be configured to convey the bias voltage 104. For example, the circuit 108 can be a voltage doubler circuit. For example, the circuit 108 can be an integrated circuit chip. For example, the circuit 108 can be a surface mount device. Optionally, the circuit 108 can be mounted on the printed circuit board 120.

Optionally, the system 102 can include a first Zener diode 126 and a second Zener diode 128. An anode of the first Zener diode 126 can be coupled to a first electrode 130 of the first pair of electrodes 116. An anode of the second Zener diode 128 can be coupled to a second electrode 132 of the first pair of electrodes 116. A cathode of the second Zener diode 128 can be coupled to a cathode of the first Zener diode 126. In this configuration, the first Zener diode 126 and the second Zener diode 128 can act to maintain a voltage of the first electrical energy 118 at a constant level. For example, the first Zener diode 126, the second Zener diode 128, or both can be Part Number MM3Z3V0ST1G manufactured by ON Semiconductor of Phoenix, Ariz. Optionally, the first Zener diode 126, the second Zener diode 128, or both can be mounted on the printed circuit board 120.

Optionally, the system 102 can include a capacitive transducer 134. The capacitive transducer 134 can be configured to receive a second portion 136 of the acoustic energy 112. The capacitive transducer 134 can have a second pair of electrodes 138. The second pair of electrodes 138 can include a first electrode 140 of the second pair of electrodes 138 and a second electrode 142 of the second pair of electrodes 138. The second pair of electrodes 138 can be configured to receive the bias voltage 104. The second pair of electrodes 138 can be configured to convey a second electrical energy 144. For example, the capacitive transducer 134 can be a microelectromechanical device. For example, the capacitive transducer 134 can be a surface mount device. Optionally, the capacitive transducer 134 can be mounted on the printed circuit board 120.

Optionally, the system 102 can be a component of an electrical device 146. The electrical device 146 can be configured to use the second electrical energy 144 as an electrical power for the electrical device 146. Optionally, at least one other component 148 of the electrical device 146 can be mounted on the printed circuit board 120. A ratio of the second electrical energy 144 to the second portion 136 of the acoustic energy 112 can be greater than a ratio of the first electrical energy 118 to the first portion 110 of the acoustic energy 112. In this manner, the electrical power for the electrical device 146 can be acoustically produced efficiently by the capacitive transducer 134 by having the required bias voltage 104 produced by the piezoelectric transducer 106.

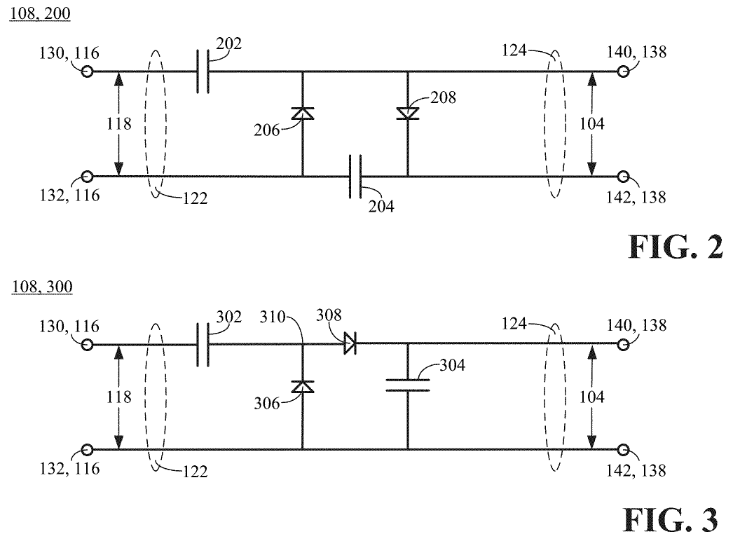

FIG. 2 is a schematic diagram illustrating an example 200 of the circuit 108 according to the disclosed technologies. The example 200 of the circuit 108 can include a first capacitor 202, a second capacitor 204, a first diode 206, and a second diode 208. The first capacitor 202 can be coupled between the first electrode 130 of the first pair of electrodes 116 and the first electrode 140 of the second pair of electrodes 138. The second capacitor 204 can be coupled between the second electrode 132 of the first pair of electrodes 116 and the second electrode 142 of the second pair of electrodes 138. An anode of the first diode 206 can be coupled to the second electrode 132 of the first pair of electrodes 116. A cathode of the first diode 206 can be coupled to the first electrode 140 of the second pair of electrodes 138. An anode of the second diode 208 can be coupled to the first electrode 140 of the second pair of electrodes 138. A cathode of the second diode 208 can be coupled to the second electrode 142 of the second pair of electrodes 138. In an implementation, the first capacitor 202, the second capacitor 204, or both can have a capacitance of one microfarad and can be rated for 100 volts. For example, the first diode 206, the second diode 208, or both can be Part Number CUS08F30, H3F manufactured by Toshiba Corporation of Minato, Tokyo, Japan.

FIG. 3 is a schematic diagram illustrating another example 300 of the circuit 108 according to the disclosed technologies. The example 300 of the circuit 108 can include a first capacitor 302, a second capacitor 304, a first diode 306, and a second diode 308. The first capacitor 302 can be coupled between the first electrode 130 of the first pair of electrodes 116 and a node 310. The second capacitor 304 can be coupled between the first electrode 140 of the second pair of electrodes 138 and the second electrode 142 of the second pair of electrodes 138. An anode of the first diode 306 can be coupled to the second electrode 132 of the first pair of electrodes 116. The second electrode 132 of the first pair of electrodes 116 can be coupled to the second electrode 142 of the second pair of electrodes 138. A cathode of the first diode 306 can be coupled to the node 310. An anode of the second diode 308 can be coupled to the node 310. A cathode of the second diode 308 can be coupled to the first electrode 140 of the second pair of electrodes 138.

With reference to FIGS. 2 and 3, the first electrical energy 118, as an alternating voltage, can be received at the input 122 of the circuit 108. In response to a voltage at the second electrode 132 being greater than a voltage at the first electrode 130, the first capacitor 202/302 can be charged through the (forward biased) first diode 206/306 to a voltage equal to a peak voltage associated with the alternating voltage. In response to the voltage at the first electrode 130 being greater than the second electrode 132, the second capacitor 204/304 can be charged both: (1) through the (forward biased) second diode 208/308 and (2) from the first capacitor 202/302 (because the first diode 206/306 is reverse biased) to a voltage equal to twice the peak voltage associated with the alternating voltage. In this manner, the bias voltage 104, as a constant voltage equal to twice the peak voltage associated with the alternating voltage, can be conveyed from the output 124 of the circuit 108.

One of skill in the art in light of the description herein understands that the circuit 108 can be realized by another example of the circuit 108 and that such another circuit can be different from a voltage doubler circuit.

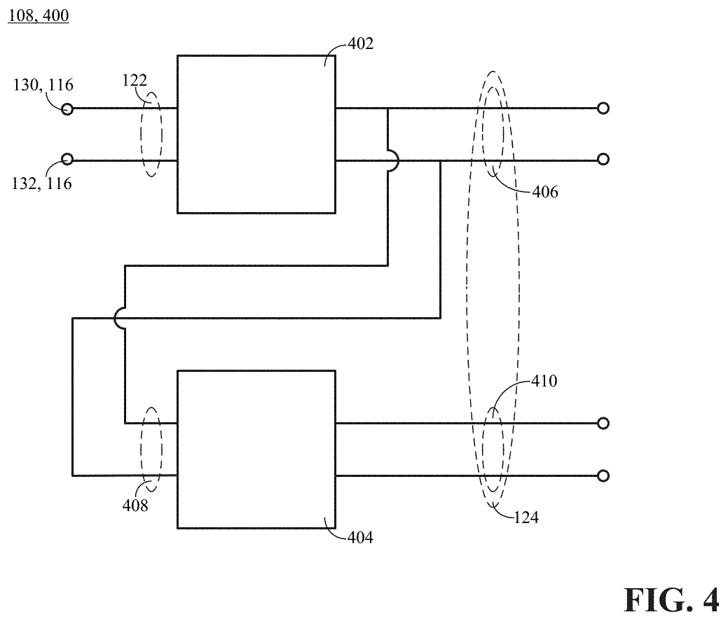

FIG. 4 is a block diagram illustrating yet another example 400 of the circuit 108 according to the disclosed technologies. The example 400 of the circuit 108 can include a first stage 402 and a second stage 404. For example, at least one of the first stage 402, the second stage 404, or both can include, as a basic circuit, the example 200 of the circuit 108, the example 300 of the circuit 108, or another example of the circuit 108 (which can be different from a voltage doubler circuit). An output 406 of the first stage 402 can be an input 408 of the second stage 404. For example, if both the first stage 402 and the second stage 404 are voltage doubler circuits, then the bias voltage 104, conveyed from the output 124 of the circuit 108, can be a constant voltage equal to four times the peak voltage associated with the alternating voltage of the first electrical energy 118 received at the input 122 of the circuit 108.

Optionally, the output 122 of the circuit 108 can include the output 406 of the first stage 402 and an output 410 of the second stage 404. For example, if both the first stage 402 and the second stage 404 are voltage doubler circuits, then the bias voltage 104, conveyed from the output 124 of the circuit 108, can be selectable from among: (1) the output 406 of the first stage 402 (a constant voltage equal to twice the peak voltage associated with the alternating voltage of the first electrical energy 118 received at the input 122 of the circuit 108) and (2) the output 410 of the second stage 404 (a constant voltage equal to four times the peak voltage associated with the alternating voltage of the first electrical energy 118 received at the input 122 of the circuit 108).

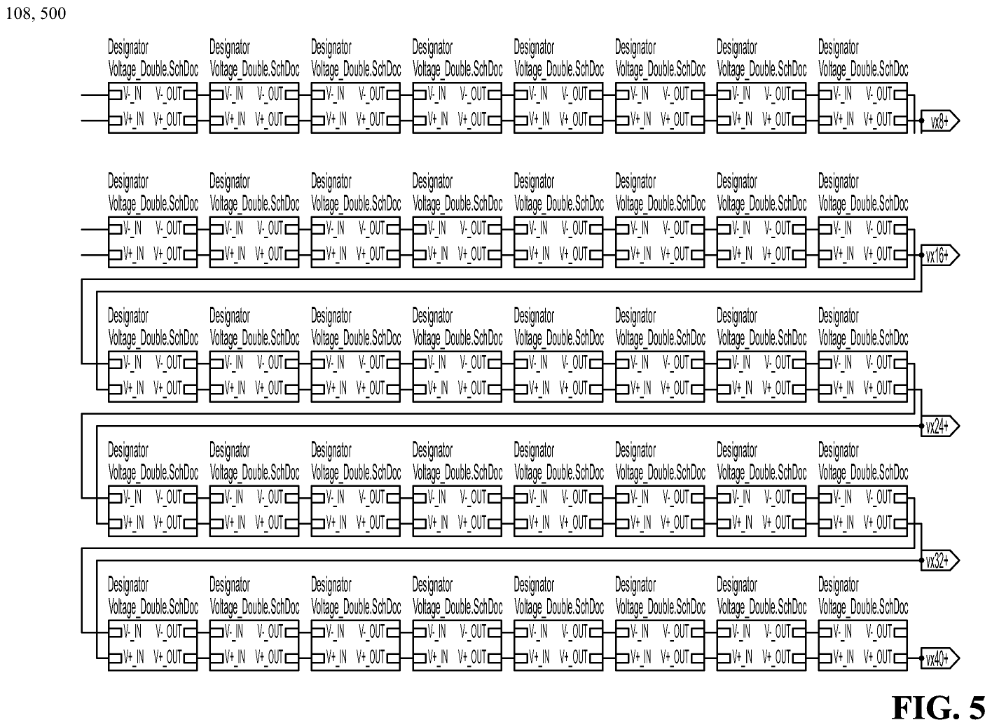

One of skill in the art in light of the description herein understands that the circuit 108 can be realized by another example of the circuit 108 and that such another circuit can have more than two stages and that selectable outputs can be associated with various stages. For example, FIG. 5 is a block diagram illustrating still another example 500 of the circuit 108 according to the disclosed technologies. The example 500 of the circuit 108 can have 40 stages in which each stage can include, as a basic circuit, a voltage doubler circuit. The example 500 of the circuit 108 can have five selectable outputs such that an output can be received after each set of eight series-coupled basic circuits.

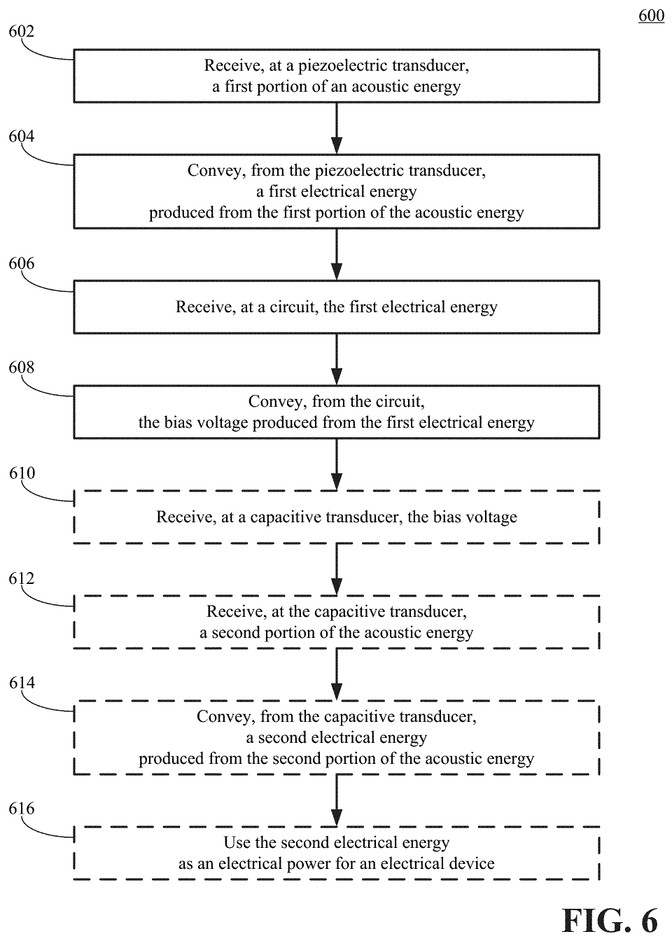

FIG. 6 is a flow diagram illustrating an example of a method 600 for producing a bias voltage according to the disclosed technologies. In the method 600, at an operation 602, a first portion of an acoustic energy can be received at a piezoelectric transducer. For example, the acoustic energy can include a sound wave at an ultrasound frequency. For example, the acoustic energy can be transmitted by an ultrasonic transmitter. For example, the piezoelectric transducer can be the piezoelectric transducer 106 of the system 100 for producing the bias voltage.

At an operation 604, a first electrical energy, produced from the first portion of the acoustic energy, can be conveyed from the piezoelectric transducer. For example, the piezoelectric transducer can have a first pair of electrodes and the first electrical energy can be conveyed by the first pair of electrodes. For example, the first pair of electrodes can be the first pair of electrodes 116 of the piezoelectric transducer 106 of the system 100 for producing the bias voltage.

At an operation 606, the first electrical energy can be received at a circuit. For example, the circuit can have an input and the input can receive the first electrical energy. For example, the input can be the input 122 of the circuit 108 of the system 100 for producing the bias voltage.

At an operation 608, the bias voltage 104, produced from the first electrical energy, can be conveyed from the circuit. For example, the circuit can have an output and the output can convey the bias voltage. For example, the output can be the output 124 of the circuit 108 of the system 100 for producing the bias voltage.

Optionally, at an operation 610, the bias voltage can be received at a capacitive transducer. For example, the capacitive transducer can have a second pair of electrodes and the bias voltage can be received by the second pair of electrodes. For example, the capacitive transducer can be the capacitive transducer 134 of the system 100 for producing the bias voltage. For example, the second pair of electrodes can be the second pair of electrodes 138 of the capacitive transducer 134.

Optionally, at an operation 612, a second portion of the acoustic energy can be received at the capacitive transducer. For example, the capacitive transducer can be the capacitive transducer 134 of the system 100 for producing the bias voltage.

Optionally, at an operation 614, a second electrical energy, produced from the second portion of the acoustic energy, can be conveyed from the capacitive transducer. For example, the capacitive transducer can have a second pair of electrodes and the second electrical energy can be conveyed by the second pair of electrodes. For example, the capacitive transducer can be the capacitive transducer 134 of the system 100 for producing the bias voltage. For example, the second pair of electrodes can be the second pair of electrodes 138 of the capacitive transducer 134.

Optionally, at an operation 616, the second electrical energy can be used as an electrical power for an electrical device. A ratio of the second electrical energy to the second portion of the acoustic energy can be greater than a ratio of the first electrical energy to the first portion of the acoustic energy. In this manner, the electrical power for the electrical device can be acoustically produced efficiently by the capacitive transducer by having the required bias voltage produced by the piezoelectric transducer.

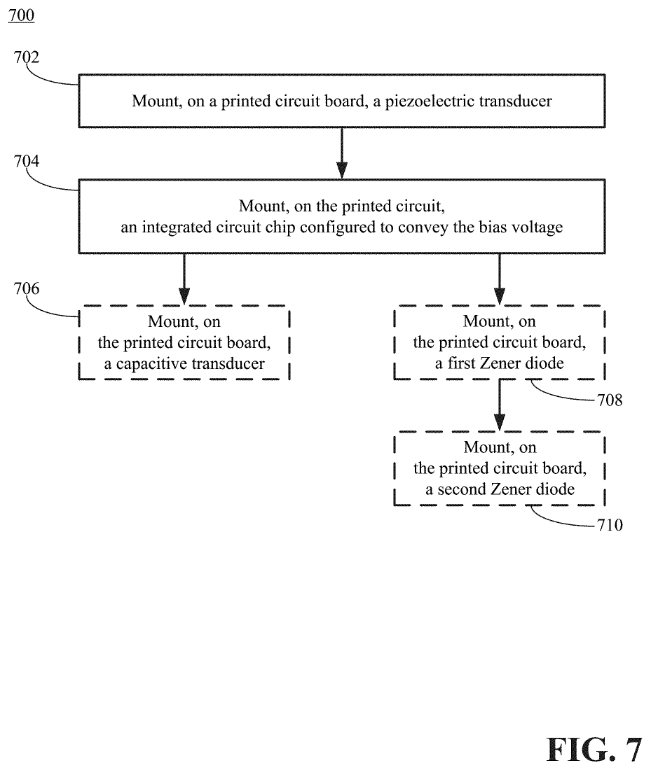

FIG. 7 is a flow diagram illustrating an example of a method 700 for making a system for producing a bias voltage according to the disclosed technologies. In the method 700, at an operation 702, a piezoelectric transducer can be mounted on a printed circuit board. The piezoelectric transducer can be configured to receive a first portion of an acoustic energy. The piezoelectric transducer can have a first pair of electrodes. The first pair of electrodes can be configured to convey a first electric energy. For example, the piezoelectric transducer can be a microelectromechanical device. For example, piezoelectric transducer can be a surface mount device. Optionally, the printed circuit board can be a component of the electrical device. Optionally, at least one other component of the electrical device can be mounted on the printed circuit board.

At an operation 704, an integrated circuit chip can be mounted on the printed circuit board. The integrated circuit chip can have an input and an output. The input can be configured to receive the first electrical energy. The output can be configured to convey the bias voltage. For example, the integrated circuit chip can be a surface mount device.

Optionally, at an operation 706, a capacitive transducer can be mounted on the printed circuit board. The capacitive transducer can be configured to receive a second portion of the acoustic energy. The capacitive transducer can have a second pair of electrodes configured to receive the bias voltage. The capacitive transducer can be configured to convey a second electrical energy. For example, the capacitive transducer can be a microelectromechanical device. For example, capacitive transducer can be a surface mount device.

Optionally, at an operation 708, a first Zener diode can be mounted on the printed circuit board. An anode of the first Zener diode can be coupled to a first electrode of the first pair of electrodes. Optionally, at an operation 710, a second Zener diode can be mounted on the printed circuit board. An anode of the second Zener diode can be coupled to a second electrode of the first pair of electrodes. A cathode of the second Zener diode can be coupled to a cathode of the first Zener diode. For example, the first Zener diode, the second Zener diode, or both can be Part Number MM3Z3V0ST1G manufactured by ON Semiconductor of Phoenix, Ariz.

The foregoing description, for purpose of explanation, has been described with reference to specific aspects. However, the illustrative discussions above are not intended to be exhaustive or to limit aspects of the disclosed technologies to the precise forms disclosed. Many modifications and variations are possible in view of the above teachings. The aspects were chosen and described in order to explain the principles of aspects of the disclosed technologies and their practical applications, to thereby enable others skilled in the art to utilize those aspects as well as various aspects with various modifications as may be suited to the particular use contemplated.

1. A system for producing a bias voltage, the system comprising:
a piezoelectric transducer configured to receive a first portion of an acoustic energy, the piezoelectric transducer having a first pair of electrodes configured to convey a first electrical energy; and
a circuit having an input and an output, the input configured to receive the first electrical energy, the output configured to convey the bias voltage.

2. The system of claim 1, further comprising a capacitive transducer configured to receive a second portion of the acoustic energy, the capacitive transducer having a second pair of electrodes configured to receive the bias voltage and to convey a second electrical energy.

3. The system of claim 2, wherein the piezoelectric transducer, the circuit, and the capacitive transducer are connected to a printed circuit board.

4. The system of claim 2, wherein the system is a component of an electrical device, the electrical device configured to use the second electrical energy as an electrical power for the electrical device.

5. The system of claim 4, wherein the piezoelectric transducer, the circuit, the capacitive transducer, and at least one other component of the electrical device are connected to a printed circuit board.

6. The system of claim 2, wherein the circuit comprises:
a first capacitor coupled between a first electrode of the first pair of electrodes and a first electrode of the second pair of electrodes;
a second capacitor coupled between a second electrode of the first pair of electrodes and a second electrode of the second pair of electrodes;
a first diode, an anode of the first diode coupled to the second electrode of the first pair of electrodes, a cathode of the first diode coupled to the first electrode of the second pair of electrodes; and
a second diode, an anode of the second diode coupled to the first electrode of the second pair of electrodes, a cathode of the second diode coupled to the second electrode of the second pair of electrodes.

7. The system of claim 2, wherein the circuit comprises:
a first capacitor coupled between a first electrode of the first pair of electrodes and a node;
a second capacitor coupled between a first electrode of the second pair of electrodes and a second electrode of the second pair of electrodes;
a first diode, an anode of the first diode coupled to a second electrode of the first pair of electrodes, the second electrode of the first pair of electrodes coupled to the second electrode of the second pair of electrodes, a cathode of the first diode coupled to the node; and
a second diode, an anode of the second diode coupled to the node, a cathode of the second diode coupled to the first electrode of the second pair of electrodes.

8. The system of claim 1, wherein the circuit comprises a first stage and a second stage, an output of the first stage being an input of the second stage.

9. The system of claim 8, wherein the output of the circuit comprises:
the output of the first stage; and
an output of the second stage.

10. The system of claim 1, further comprising:
a first Zener diode, an anode of the first Zener diode coupled to a first electrode of the first pair of electrodes; and
a second Zener diode, an anode of the second Zener diode coupled to a second electrode of the first pair of electrodes, a cathode of the second Zener diode coupled to a cathode of the first Zener diode.

11. A method for producing a bias voltage, the method comprising:
receiving, at a piezoelectric transducer, a first portion of an acoustic energy;
conveying, from the piezoelectric transducer, a first electrical energy produced from the first portion of the acoustic energy;
receiving, at a circuit, the first electrical energy; and
conveying, from the circuit, the bias voltage produced from the first electrical energy.

12. The method of claim 11, wherein the acoustic energy comprises a sound wave at an ultrasound frequency.

13. The method of claim 11, further comprising:
receiving, at a capacitive transducer, the bias voltage;
receiving, at the capacitive transducer, a second portion of the acoustic energy; and
conveying, from the capacitive transducer, a second electrical energy produced from the second portion of the acoustic energy.

14. The method of claim 13, further comprising using the second electrical energy as an electrical power for an electrical device.

15. The method of claim 13, wherein a ratio of the second electrical energy to the second portion of the acoustic energy is greater than a ratio of the first electrical energy to the first portion of the acoustic energy.

16. A method for making a system for producing a bias voltage, the method comprising:
mounting, on a printed circuit board, a piezoelectric transducer configured to receive a first portion of an acoustic energy, the piezoelectric transducer having a first pair of electrodes configured to convey a first electrical energy; and
mounting, on the printed circuit board, an integrated circuit chip, the integrated circuit chip having an input and an output, the input configured to receive the first electrical energy, the output configured to convey the bias voltage.

17. The method of claim 16, further comprising
mounting, on the printed circuit board, a capacitive transducer, the capacitive transducer configured to receive a second portion of the acoustic energy, the capacitive transducer having a second pair of electrodes configured to receive the bias voltage and to convey a second electrical energy.

18. The method of claim 17, wherein the printed circuit board is a component of an electrical device.

19. The method of claim 18, wherein at least one other component of the electrical device is mounted on the printed circuit board.

20. The method of claim 16, further comprising:
mounting, on the printed circuit board, a first Zener diode, an anode of the first Zener diode coupled to a first electrode of the first pair of electrodes; and
mounting, on the printed circuit board, a second Zener diode, an anode of the second Zener diode coupled to a second electrode of the first pair of electrodes, a cathode of the second Zener diode coupled to a cathode of the first Zener diode.
